(19) United States
(12) Patent Application Publication
(10) Pub. No.: US 2004/0217421 A1
(43) Pub. Date: Nov. 4, 2004

(54) SOI field effect transistor element having an ohmic substrate contact

(76) Inventors: Massud Aminpur, Dresden (DE); Gert Burbach, Dresden (DE)

Correspondence Address: J. Mike Amerson, Williams, Morgan & Amerson, P.C., Suite 1100, 10333 Richmond, Houston, TX, 77042, US

(21) Appl. No.: 10/651,061

(22) Filed: Aug. 28, 2003

(30) Foreign Application Priority Data
Apr. 30, 2003 (GB) 103 19 497.5

(51) Int. Cl. H01L 27/01

(52) U.S. Cl. 257/347

(57) ABSTRACT

A substantially ohmic substrate contact may be formed in an SOI semiconductor device by using a conductive material, such as aluminum, for the substrate contact that forms an ohmic contact even at low dopant concentrations, usually encountered in SOI substrates. Moreover, a process sequence is disclosed that allows the formation of the ohmic substrate contact at a high degree of compatibility with conventional dual contact approaches.

### BACKGROUND OF THE INVENTION

1. Field of the Invention

The present invention relates to the field of manufacture of integrated circuits, and, more particularly, to field effect transistors formed on an insulating substrate, such as silicon-on-insulator (SOI) devices and a method of manufacturing such devices.

2. Description of the Related Art

In modern integrated circuits, the number and, hence, the package density of circuit elements, such as field effect transistors, is steadily increasing and, as a consequence, performance of these integrated circuits is currently improving. The increase in package density and signal performance of integrated circuits requires the reduction of critical feature sizes, such as the gate length and, thus, the channel length of field effect transistors to minimize the chip area occupied by a single circuit element and to reduce signal propagation delay owing to a delayed channel formation. However, currently, critical feature sizes are approaching 0.1 μm and less and a further improvement in circuit performance by reducing the size of the transistor elements is partially offset by parasitic capacitances of the transistors formed in bulk silicon substrates.

In order to meet the ever-increasing demands with respect to device and circuit performance, circuit designers have proposed new device architectures. One technique to improve performance of a circuit, for example of a CMOS device, is to manufacture the circuit on a so-called silicon-on-insulator (SOI) substrate, wherein an insulating layer is formed on a bulk substrate, for example a silicon substrate or glass substrate, wherein the insulating layer frequently comprises silicon dioxide (also referred to as buried oxide layer). Subsequently, a silicon layer is formed on the insulating layer in which an active region for a field effect transistor device is defined by shallow trench isolations. A correspondingly fabricated transistor is entirely electrically isolated from the regions surrounding the transistor area. Contrary to a conventional device formed on a bulk semiconductor substrate, the precise spatial confinement of the active region of the SOI device significantly suppresses parasitic effects known from conventional devices, such as latch-up and leakage currents drifting into the substrate. Moreover, SOI devices are characterized by lower parasitic capacitances compared to devices formed on a bulk semiconductor substrate and, hence, exhibit an improved high frequency performance. Furthermore, due to the significantly reduced volume of the active region, radiation-induced charge carrier generation is also remarkably reduced and renders SOI devices extremely suitable for applications in radiation-intensive environments.

On the other hand, the advantages of SOI devices over conventionally fabricated devices may partially be offset by the so-called floating body effect, wherein the substrate of the device is not tied to a defined potential, which may lead to an accumulation of minority charge carriers, for example holes in an N-channel MOS transistor, below the channel region, thereby adversely affecting the transistor characteristics, such as the threshold voltage, single-transistor-latch-up, and the like. Therefore, so-called substrate contacts are frequently formed to provide a connection to the substrate.

With reference to FIGS. 1a-1b, a typical conventional process flow for forming a substrate contact will now be described in more detail. In FIG. 1a, a semiconductor device 100 is schematically shown in a cross-sectional view. The semiconductor device 100 comprises an SOI substrate 101, which in turn includes a crystalline silicon layer 102 that is typically provided in the form of a bulk silicon substrate with an insulation layer 103 formed thereon. The insulation layer 103 may often be referred to as buried oxide layer, since typically the insulating layer 103 may be comprised of silicon dioxide. However, the insulating layer 103 may, depending on the process for forming the SOI substrate 101, include other insulating materials, such as silicon nitride and the like. The SOI substrate 101 further includes a semiconducting layer 104 having a thickness that allows the formation of circuit elements such as field effect transistors 110a and 110b. The semiconducting layer 104 may be formed of a variety of materials, e.g., crystalline silicon, silicon-germanium, or any III-V and II-VI semiconductors in crystalline form, etc. Each of the field effect transistors 110a and 110b is enclosed by a trench isolation structure 105 that includes an insulating material, such as silicon oxide and/or silicon nitride. Thus, the field effect transistors 110a and 110b are formed on respective silicon islands that may be completely insulated from each other by the trench isolation structure 105 and the insulating layer 103. The field effect transistors 110a and b may include a gate electrode 111 that is separated from a channel region 113 by a gate insulation layer 112. Moreover, drain and source regions 114 may be provided within the silicon layer 104 and sidewall spacers 115 may be located at sidewalls of the gate electrode 111. The channel region 113, the drain and source regions 114 and the gate electrode 111 may comprise a dopant material with an appropriate concentration so as to provide the desired electrical performance of the transistors 110a and 110b. Moreover, silicide regions (not shown) may be formed on top of the source and drain regions 114 and the gate electrode 111 to minimize the resistance of these regions. The semiconductor device 100 further comprises a first dielectric layer 106 followed by a second dielectric layer 107, wherein a thickness of the second dielectric layer 107 is selected such that the transistors 110a and 110b are completely embedded within the second dielectric layer 107. The first dielectric layer 106 may be comprised of, for example, silicon oxynitride and the second dielectric layer 107 may be comprised of silicon dioxide. Typically, the composition and thickness of the first dielectric layer 106 may be selected so as to act as a bottom anti-reflective coating in a subsequent lithography process for forming contacts to the transistors 110a and 110b and to the silicon layer 102 of the SOI substrate 101. Moreover, the first dielectric layer 106 may act as an etch stop layer during the formation of the contact openings. A resist layer 108 is formed above the second dielectric layer 107 and has an opening 109 with dimensions that substantially represent the dimensions of a substrate contact opening to be formed.

A typical process flow for manufacturing the semiconductor device 100 as shown in FIG. 1a may comprise the following processes. The SOI substrate 101 may be formed by sophisticated wafer bonding techniques and may be purchased from corresponding manufacturers in a condition that allows the subsequent formation of the transistors 110a and 110b. Then, the trench isolation structure 105 may be formed by well-established photolithography, etch and deposition techniques to define a lithography resist mask, etch respective trenches, and subsequently deposit one or more insulating materials to fill the trenches, thereby forming the trench isolation structure 105. Thereafter, any excess material may be removed by chemical mechanical polishing (CMP), thereby also planarizing the substrate surface. Afterwards, the gate insulation layer 112 may be formed by sophisticated oxidation and/or deposition processes as are well known in the art. Subsequently, the gate electrode 111 may be formed by well-known lithography and etch techniques and implantation cycles may be carried out so as to form the drain and source regions 114 with a required dopant profile, wherein, depending on the process sequence used, the spacer elements 115 may be formed prior to, during or after the implantation sequence. Then, silicide portions may be formed in the drain and source regions 114 and the gate electrode 111 by well-established silicidation processes. After the completion of the transistors 110a and 110b, the first dielectric layer 106 may be deposited, for instance by chemical vapor deposition (CVD), wherein a thickness and a material composition is selected so as to provide the required optical characteristics and/or the desired etch selectivity to the second dielectric layer 107 in a subsequent anisotropic etch process. Thereafter, the second dielectric layer 107 may be deposited and may be planarized by CMP to provide a substantially planar surface. Next, the resist layer 108 is formed and patterned in accordance with well-established photolithography techniques, wherein the first dielectric layer 106 may act as an anti-reflective coating.

Subsequently, an etch process sequence is performed to create a substrate contact opening in the first dielectric layer 107, the second dielectric layer 106, the trench isolation structure 105, and the insulating layer 103 which connects to the silicon layer 102. To this end, in a further step, an anisotropic etch process is carried out to form an opening in the first dielectric layer 107, wherein the anisotropic etch process is substantially stopped at or within the second dielectric layer 106. Alternatively, an anisotropic etch process recipe may be used that does not exhibit a specific selectivity between the first dielectric layer 106 and the second dielectric layer 107. Then, the first dielectric layer 106 may be opened and the trench isolation structure 105 may be etched, followed by the insulating layer 103 until the etch process is stopped on or within the silicon layer 102. Thereafter, the resist layer 108 is removed, for example by plasma etching and a subsequent wet chemical clean process. The process for forming the substrate contact opening requires a plurality of etch procedures through a plurality of layers, thereby rendering the contact etch quite complex. Moreover, the etch stop layer 106 may not provide sufficient selectivity to simultaneously form openings for contacts to the transistors 110a and/or 110b, without damaging underlying device regions. Therefore, a further etch process is performed to form corresponding contact openings.

To this end, a further resist mask (not shown) is then formed to define respective openings for contacts to the gate electrode 111 and the drain and/or source regions 114. Thereafter, a selective anisotropic etch process is carried out to form contact openings in the second dielectric layer 107, wherein the etch process is stopped within the first dielectric layer 106, which is then opened by a subsequent selective etch step to provide a connection to the gate electrode 111 and the drain and/or source regions 114. Finally, the second resist layer is removed by, for example, a similar process as in the case of the resist layer 108 in FIG. 1a.

FIG. 1b schematically shows the semiconductor device 100 after the above-described sequence is completed. Thus, the semiconductor device 100 comprises a substrate contact opening 120, a gate contact opening 121 and, for example, one contact opening 122 connecting to the source region of the transistor 110a. Subsequently, the openings 120, 121 and 122 are filled with a highly conductive metal, such as tungsten, which is presently considered as a preferred candidate for a contact metal of high-end copper-based devices, connecting circuit elements to further metallization layers (not shown) of the semiconductor device 100. The tungsten may be filled in by well-established deposition techniques, such as chemical and physical vapor deposition techniques. Thereafter, excess tungsten is removed by a CMP process, thereby also planarizing the substrate surface for the further processing of the device 100 so as to form one or more metallization layers.

Although a conductive connection to the silicon layer 102 of the SOI substrate 101 is established by the substrate contact 120 (for convenience, the opening 120 filled with tungsten is referred to as the “substrate contact”), the electrical contact formed on an interface 123 between the tungsten and the silicon layer 122 behaves like a Schottky contact due to the relatively low dopant concentration in the silicon layer 102 and the moderate work function of tungsten. Consequently, during operation of the semiconductor device 100, charge carriers exchange between a voltage source connected to the substrate contact 120 and the silicon layer 102 may be degraded, thereby significantly adversely influencing the operation of the semiconductor device 100, since the silicon layer 102 may not be efficiently prevented from floating.

Due to the plurality of superior characteristics of SOI devices compared to devices formed on bulk silicon substrates and due to the availability of SOI substrates at low cost having silicon layers formed thereon with high quality, the development of SOI devices will gain in importance. Thus, an urgent need exists for an improved substrate contact technique that allows the formation of substrate contacts having a substantially ohmic behavior, to thereby improve the performance of SOI transistor elements.

### SUMMARY OF THE INVENTION

The present invention is directed to a technique that enables the formation of substantially ohmic substrate contacts in that a conductive material, such as aluminum, is used that forms a substantially ohmic contact even at low dopant concentrations typically provided in crystalline regions below a buried insulation layer of an SOI substrate. In a further aspect, the dopant concentration may be adapted so as to form a substantially ohmic contact with a desired contact material.

According to one illustrative embodiment of the present invention, a semiconductor device comprises a silicon substrate having formed thereon an insulating layer. A crystalline semiconductor region is formed on the insulating layer and is enclosed by a trench isolation structure. Moreover, a substrate contact comprised of aluminum is formed through the trench isolation structure so as to connect to the silicon substrate.

According to a further illustrative embodiment of the present invention, an SOI device comprises a silicon substrate having formed thereon a buried insulating layer. A plurality of circuit elements are formed above the buried insulating layer and electrically insulated from each other by trench isolation structures. A substrate contact is formed through at least one of the trench isolation structures, wherein the substrate contact is comprised of a material that forms a substantially ohmic contact with the silicon substrate.

According to still a further illustrative embodiment of the present invention, a method comprises forming a substrate contact opening in a dielectric layer and a trench isolation structure enclosing a circuit element formed on an SOI substrate, wherein the dielectric layer is located above the trench isolation structure. Then, aluminum is deposited over the dielectric layer to fill the substrate contact opening and to form a substrate contact to the SOI substrate. Next, excess aluminum is removed from the dielectric layer and at least one contact is formed that connects to the circuit element.

According to another illustrative embodiment of the present invention, a method of forming a substantially ohmic substrate contact in an SOI semiconductor device comprises forming a substrate contact opening through a trench isolation structure enclosing a circuit element, wherein the substrate contact opening connects to a crystalline region of the SOI substrate. Then, the substrate contact opening is filled with a conductive material selected so as to provide a substantial ohmic contact to the crystalline region. Finally, at least one contact is formed that connects to the circuit element.

According to another illustrative embodiment of the present invention, a method comprises providing an SOI substrate having formed thereon at least one circuit element enclosed by an isolation structure. Then, a substrate contact opening is formed through the isolation structure that connects to a crystalline region located below a buried insulation layer. Thereafter, a dopant concentration of the crystalline region is increased and the substrate contact opening is filled with a conductive material, wherein the increased dopant concentration provides for a substantially ohmic contact between the crystalline region and the conductive material.

### BRIEF DESCRIPTION OF THE DRAWINGS

The invention may be understood by reference to the following description taken in conjunction with the accompanying drawings, in which like reference numerals identify like elements, and in which:

FIGS. 1a-1b schematically show cross-sectional views of conventional SOI transistor elements during the formation of a substrate contact, and

FIGS. 2a-2c schematically show cross-sectional views of a semiconductor device formed on an SOI substrate having a substrate contact with a substantially ohmic behavior during various manufacturing stages in accordance with illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

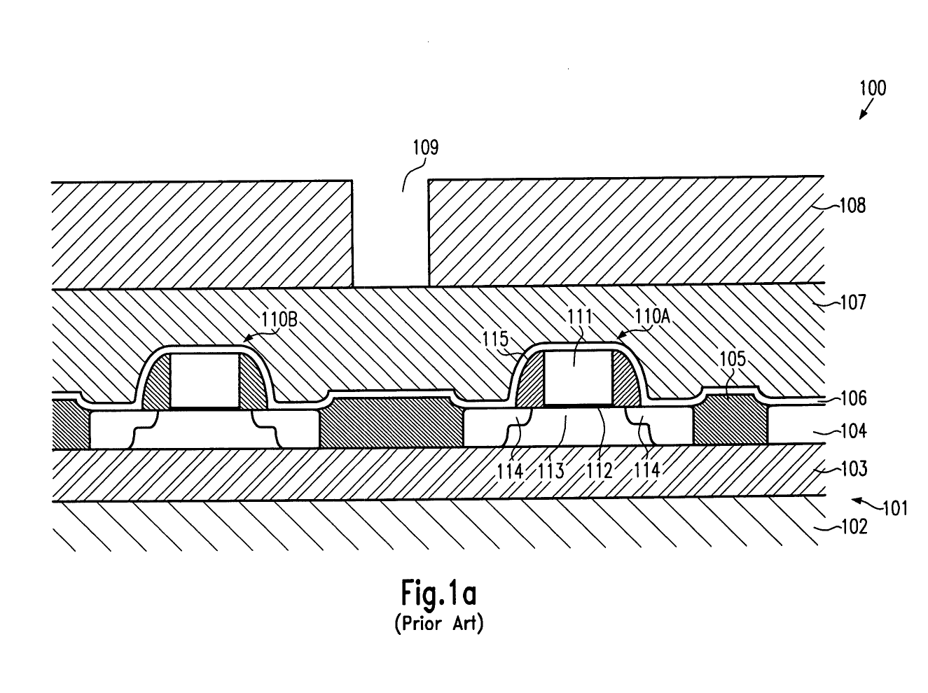

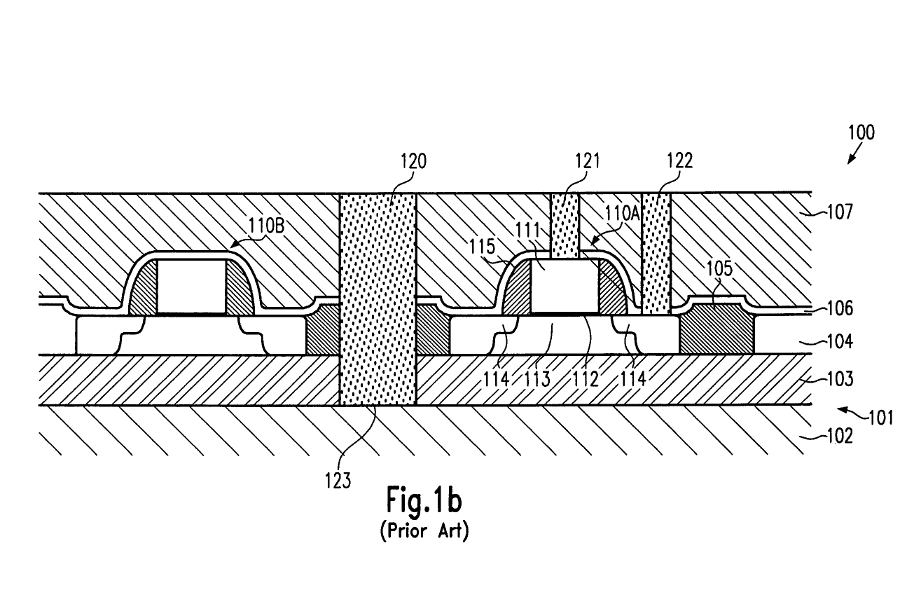

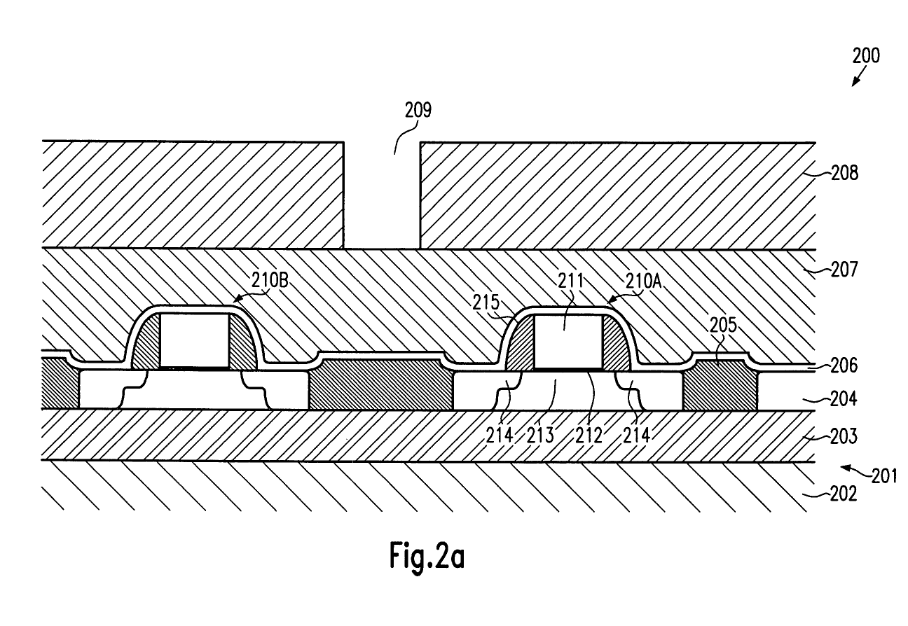

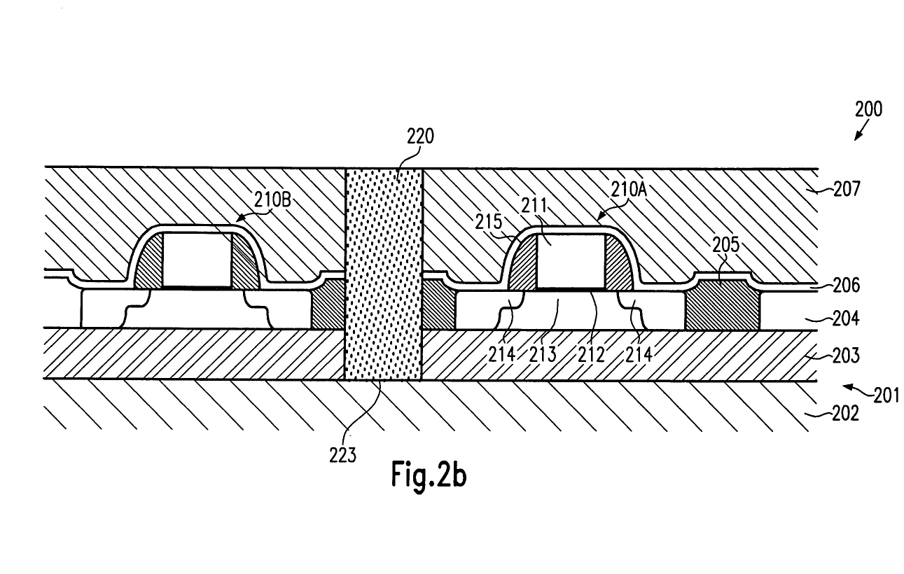

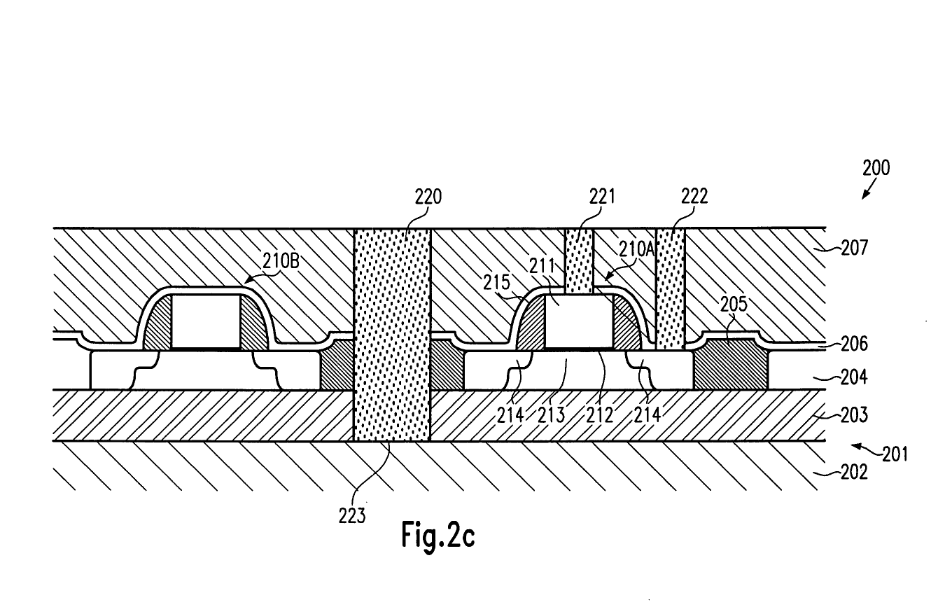

With reference to FIGS. 2a-2c, further illustrative embodiments of the present invention will now be described in more detail. In FIG. 2a there is shown a semiconductor device 200 including one or more circuit elements formed on an SOI substrate. For convenience, in these representative embodiments, the semiconductor device 200 may have substantially the same construction as the semiconductor device 100 shown in FIG. 1a. The corresponding parts and components are, however, labeled with reference numerals beginning with “2” instead of “1.” It should be appreciated, however, that the number and the type of circuit elements may be selected as is required by the circuit design, as long as the trench isolation structures 205 are provided that enclose one or more circuit elements.

A typical process flow for manufacturing the semiconductor device 200 as shown in FIG. 2a may comprise substantially the same processes as previously described with reference to FIG. 1a. Thus, an anisotropic etch process may performed to form a substrate contact opening by etching through the second dielectric layer 207, the first dielectric layer 206, the trench isolation structure 205, and the buried insulating layer 203, as is previously described. Contrary to the conventional process, according to some illustrative embodiments, the substrate contact opening may, after the removal of the resist layer 208, be filled by a conductive material that, in one particular embodiment, is substantially comprised of aluminum. To this end, an aluminum layer may be deposited by chemical vapor deposition as is well known in the art so as to fill the substrate contact opening. Thereafter, any excess aluminum may be removed by, according to one embodiment, a chemical mechanical polishing process and, according to still a further embodiment, by an etch process. Since aluminum is a well-established metal for forming metal lines in any metallization layers (not shown), corresponding recipes for depositing, chemically mechanically polishing and etching aluminum that is formed on a dielectric material, such as the dielectric layer 207, are well known in the art and these process recipes may readily be applied to filling the contact opening and removing excess aluminum.

FIG. 2b schematically shows the semiconductor device 200 with a substrate contact 220 that is conductively coupled to the silicon layer 202 of the SOI substrate 201. The substrate contact may be filled with a conductive material that is substantially comprised of aluminum, as is described above. Typically, the silicon layer 202 may be slightly pre-doped at a dopant concentration of approximately 10¹⁶ atoms/cm³. Even at this relatively low dopant concentration, aluminum forms a substantially ohmic contact with the pre-doped silicon at an interface 223, thereby providing the required performance of the semiconductor device 200 without any restrictions, as are typical for the Schottky-like contact of the conventional semiconductor device 100 of FIG. 1b.

In a further illustrative embodiment, the substrate contact 220 may be substantially comprised of doped polysilicon, which also forms a substantially ohmic contact at the interface 223. The doped polysilicon may be deposited by plasma-enhanced chemical vapor deposition in the presence of an appropriate dopant material, wherein the dopant concentration finally obtained may be controlled by adjusting the concentration of the dopant material in the deposition atmosphere. Since the dopant concentration substantially determines the conductivity of the polysilicon and thus the conductivity of the substrate contact 220, a dopant concentration in a range between approximately 10¹⁸−10²⁰ atoms/cm³ or even more may be selected depending on circuit requirements. Thereafter, any excess polysilicon material may be removed by an etch process or a CMP process. Although, in general, polysilicon, even when doped at concentrations in the above specified range, has a significantly lower conductivity compared to aluminum, in some applications, the provision of polysilicon instead of aluminum may nevertheless be a viable design alternative, especially as polysilicon has a high compatibility with the surrounding materials, such as the silicon layer 202, the buried insulation layer 203 and the trench isolation structure 205.

In a further embodiment, prior to filling in a conductive material to form the substrate contact 220, the dopant concentration in a portion of the silicon layer 202 that is exposed by the substrate contact opening for the contact 220 may be increased by, for example, an ion implantation sequence. Advantageously, the ion implantation may be carried out prior to the removal of the resist layer 208 so that any impact of the implantation sequence on the second dielectric layer 207 is minimized. In other embodiments, however, when the thickness and the composition of the resist layer 208 is deemed inappropriate for being subjected to an ion implantation process, a further resist layer (not shown) using the same lithography mask may be formed, or the ion implantation may be carried out after the removal of the resist layer 208, wherein the second dielectric layer 207 acts as an implantation mask. In this way, the dopant concentration at the interface 223 may be increased to a value that assures a substantial ohmic behavior when the initial pre-doping of the SOI substrate 201 may not be considered sufficiently high. The dose for the ion implantation may be selected within a range of approximately 10¹⁵ to 10¹⁶ ions/cm² for boron ions with a moderate energy in the range of approximately 5-50 keV. For other dopant materials, corresponding values may be selected. It may be preferable to select the implantation energy such that the penetration depth of the implant ions is low to provide a high dopant concentration at the interface 223.

In one embodiment, the dopant concentration at the interface 223 may be increased to values that even allow the formation of a substantially ohmic contact with the conventionally used contact metal tungsten. In this case, the process flow may, after implanting a corresponding dopant concentration at the interface 223, resume in accordance with the process flow described with reference to FIGS. 1a-1b. Thus, contact openings, such as the openings 121, 122, may be formed that connect to respective circuit elements, such as the transistor element 110a in FIG. 1b, and the substrate contact opening 120 and the contact openings 121 and 122 may be filled in a common deposition process. It should be noted that, in increasing the dopant concentration at the interface 223, a preferably relatively high concentration may be created since, due to the lack of any anneal cycles, the portion of the crystalline layer 202 subjected to the ion implantation process may not be recrystallized and the dopant atoms may not be effectively activated. Thus, a very high dopant concentration in the range of approximately 10²⁰−10²¹ atoms/cm³ may provide for a sufficient conductivity despite the implantation-induced crystal damage and the insufficiently activated dopant atoms.

In other embodiments, the increase of the dopant concentration at the interface 223 may be accomplished by a plasma treatment, wherein the plasma atmosphere includes a high amount of dopant material that may be incorporated into the layer 202 without excessively damaging the crystalline structure of the layer 202. Although only a very restricted surface portion at the interface 223 may then comprise a high dopant concentration, a substantially ohmic contact may nevertheless be achieved for a plurality of materials, such as tungsten.

Again referring to FIG. 2b, after the formation of the substrate contact 220, a further resist mask for defining contact openings for the one or more circuit elements 210a and 210b may be formed, followed by an anisotropic etch procedure to form contact openings corresponding to the resist mask in a process that may be similar to that described with reference to FIG. 1a.

FIG. 2c schematically shows the semiconductor device 200 with the contact openings 221 and 222 connecting to the gate electrode 211 and the source region 214, respectively, wherein the resist mask has previously been removed by a plasma etch process and a subsequent wet chemical cleaning process.

Next, the contact openings 221 and 222 may be filled with tungsten to form contacts, similarly as in the conventional device shown in FIG. 1b, and thereafter any excess tungsten may be removed by a CMP process.

Finally, one or more metallization layers (not shown) are formed, wherein, in particular embodiments, the metallization layers include copper lines and vias embedded in a dielectric material, which, in illustrative embodiments, may be comprised of low-k dielectrics, such as SICOH, SiCN, and the like.

As a result, the present invention allows the formation of substrate contacts that exhibit a substantially ohmic behavior, wherein well-established processes may be used, such as the deposition and the removal of aluminum or polysilicon or any other conductive materials that form a substantially ohmic contact to the substrate in its pre-doped form. These processes may readily be implemented into the conventional process flow, thereby providing a high degree of compatibility to the conventional process flow. Moreover, the dopant concentration of the silicon substrate may be increased in such a manner that other metals, such as tungsten, may form a substantially ohmic contact, thereby allowing the formation of SOI devices lacking the performance restriction imparted by the Schottky behavior of conventional substrate contacts.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A semiconductor device, comprising:
a silicon substrate having formed thereon an insulating layer;
at least one semiconductor region formed on said insulating layer and being enclosed by a trench isolation structure; and
a substrate contact comprised of aluminum that extends through said trench isolation structure so as to connect to said silicon substrate.

2. The semiconductor device of claim 1, wherein said silicon substrate is doped at a concentration of approximately 10¹⁶ atoms/cm³ or more.

3. The semiconductor device of claim 1, further comprising a field effect transistor element formed in and on said semiconductor region, said field effect transistor element having drain, source and gate contacts that are comprised of a metal other than aluminum.

4. The semiconductor device of claim 3, wherein said drain, source and gate contacts are comprised of tungsten.

5. An SOI device, comprising:
a silicon substrate having formed thereon a buried insulating layer;
a plurality of circuit elements formed above said buried insulating layer and electrically insulated from each other by trench isolation structures; and
a substrate contact formed through at least one of said trench isolation structures, wherein said substrate contact is comprised of a material that forms a substantially ohmic contact with said silicon substrate.

6. The SOI device of claim 5, wherein said substrate contact comprises aluminum.

7. The SOI device of claim 5, wherein said substrate contact comprises doped polysilicon.

8. The SOI device of claim 6, wherein said silicon substrate is doped at a concentration of approximately 10¹⁶ atoms/cm³ or more.

9. The SOI device of claim 5, wherein at least one of said circuit elements is a field effect transistor having drain, source and gate contacts comprised of tungsten.

10. A method, comprising:
forming a substrate contact opening in a dielectric layer and a trench isolation structure that encloses a circuit element formed on an SOI substrate, said dielectric layer being located above said trench isolation structure;
depositing aluminum over said dielectric layer to fill said substrate contact opening and form a substrate contact to said SOI substrate;
removing excess aluminum from said dielectric layer; and
forming contacts to said circuit element.

11. The method of claim 10, wherein said excess aluminum is removed by at least one of chemical mechanical polishing and etching.

12. The method of claim 10, wherein forming said contacts to said circuit element includes forming one or more contact holes connecting to said circuit element and filling said contact holes with a conductive material.

13. The method of claim 12, wherein said conductive material comprises tungsten.

14. The method of claim 10, further comprising locally increasing a dopant concentration of said SOI substrate within said substrate contact opening prior to filling in said aluminum.

15. The method of claim 14, wherein said dopant concentration is 10¹⁶ dopant atoms/cm³ or more.

16. The method of claim 14, wherein said dopant concentration is increased by an ion implantation process.

17. A method of forming a substantially ohmic substrate contact in an SOI semiconductor device, the method comprising:
forming a substrate contact opening through a trench isolation structure enclosing a circuit element, said substrate contact opening connecting to a crystalline region of said SOI substrate;
filling said substrate contact opening with a conductive material selected so as to provide a substantially ohmic contact to said crystalline region; and
forming at least one contact to said circuit element after filling said substrate contact opening.

18. The method of claim 17, wherein said conductive material comprises at least one of doped polysilicon and aluminum.

19. The method of claim 18, further comprising removing excess material of said conductive material by at least one of chemical mechanical polishing and etching.

20. The method of claim 19, wherein filling in said conductive material includes depositing polysilicon in the presence of a dopant material.

21. The method of claim 21, wherein a dopant concentration of said polysilicon after deposition is approximately 10²⁰ dopant atoms/cm³ or more.

22. A method, comprising:
providing an SOI substrate having formed thereon at least one circuit element enclosed by an isolation structure;
forming a substrate contact opening through said isolation structure that connects to a crystalline region located below a buried insulation layer;
increasing a dopant concentration of said crystalline region; and
filling said substrate contact opening with a conductive material, wherein said increased dopant concentration provides for a substantially ohmic contact between said crystalline region and said conductive material.

23. The method of claim 22, wherein said dopant concentration is increased by an ion implantation process performed after forming said substrate contact opening.

24. The method of claim 22, wherein said conductive material comprises one of aluminum, polysilicon and tungsten.

25. The method of claim 22, further comprising forming at least one contact opening connecting to said circuit element and filling said at least one contact opening with a second conductive material.

26. The method of claim 25, wherein said at least one contact opening is filled after filling said substrate contact opening.

27. The method of claim 25, wherein said substrate contact opening and said at least one contact opening are filled in a common fill process.

28. The method of claim 26, further comprising removing excess material after filling said substrate contact opening by one of chemical mechanical polishing and etching.

29. The method of claim 28, wherein said conductive material comprises aluminum and said second conductive material comprises tungsten.
